(19) United States
(12) Patent Application Publication
(10) Pub. No.: US 2025/0041989 A1
(43) Pub. Date: Feb. 6, 2025

(54) POLISHING APPARATUS

(71) Applicant: EBARA CORPORATION, Tokyo (JP)

(72) Inventor: Masaki KINOSHITA, Tokyo (JP)

(21) Appl. No.: 18/782,148

(22) Filed: Jul. 24, 2024

(30) Foreign Application Priority Data
Aug. 1, 2023 (JP) 2023-125457

(51) Int. Cl. B24B 53/017; B24B 49/04; B24B 49/12

(52) U.S. Cl. CPC B24B 53/017; B24B 49/12; B24B 49/04

(57) ABSTRACT

A polishing apparatus capable of preventing abrasive grains in a polishing liquid and polishing debris of a workpiece from adhering to an optical sensor head and capable of improving a measuring accuracy of a film thickness of a workpiece is disclosed. The polishing apparatus includes: a polishing table configured to support a polishing pad having a through-hole; a polishing head configured to press a workpiece against the polishing pad; an optical film-thickness measuring system having an optical sensor head disposed below the polishing pad; and a sensor-head cleaning nozzle configured to emit a cleaning liquid to the optical sensor head. The sensor-head cleaning nozzle is disposed in the polishing table and points at the optical sensor head.

### CROSS REFERENCE TO RELATED APPLICATION

This document claims priority to Japanese Patent Application No. 2023-125457 filed Aug. 1, 2023, the entire contents of which are hereby incorporated by reference.

### BACKGROUND

A chemical mechanical polishing (CMP) apparatus configured to polish a surface of a workpiece, such as a wafer, is used in a manufacturing process of semiconductor devices. The CMP apparatus includes a polishing table to which a polishing pad is attached, and a polishing head configured to press the workpiece against a polishing surface of the polishing pad. The CMP apparatus presses the workpiece against the polishing surface of the polishing pad by the polishing head while supplying a polishing liquid (e.g., slurry) onto the polishing pad to thereby place the surface of the workpiece in sliding contact with the polishing surface of the polishing pad. The surface of the workpiece is polished by a chemical action of the polishing liquid and mechanical action(s) of abrasive grains contained in the polishing liquid and/or the polishing pad.

Polishing of the workpiece is terminated when a thickness of a film (e.g., a dielectric film, a silicon layer, etc.), constituting the surface of the workpiece, has reached a target film thickness. The polishing apparatus includes an optical film-thickness measuring system configured to measure the film thickness of the workpiece. The optical film-thickness measuring system is configured to direct light onto the workpiece and receive reflected light from the workpiece by an optical sensor head disposed in the polishing table, produce a spectrum of the reflected light from intensity of the reflected light, and determine the film thickness of the workpiece based on the spectrum of the reflected light.

In order to stabilize the measuring of the film-thickness performed by the optical film-thickness measuring system, it is necessary to keep the light path clean. For example, patent document 1 describes a method of limiting intrusion of polishing liquid and polishing debris by filling a light path with a transparent liquid.

However, the abrasive grains contained in the polishing liquid and the polishing debris of the workpiece usually have a larger specific gravity than the transparent liquid. As a result, the abrasive grains and the polishing debris may adhere to the optical sensor head. When the abrasive grains and the polishing debris adhere to the optical sensor head, a measured value of intensity of the reflected light from the workpiece decreases. As a result, the optical film-thickness measuring system may not accurately measure the film thickness.

### SUMMARY

Therefore, there is provided a polishing apparatus capable of preventing abrasive grains in a polishing liquid and polishing debris of a workpiece from adhering to an optical sensor head and capable of improving a measuring accuracy of a film thickness of a workpiece.

Embodiments, which will be described below, relate to a technique of polishing a workpiece, such as a wafer, an interconnect substrate, a quadrangular substrate, and more particularly to a technique of directing light to the workpiece through a through-hole of a polishing pad for polishing the workpiece and measuring a film thickness of the workpiece based on spectrum of reflected light from the workpiece.

In an embodiment, there is provided a polishing apparatus comprising: a polishing table configured to support a polishing pad having a through-hole; a polishing head configured to press a workpiece against the polishing pad; an optical film-thickness measuring system having an optical sensor head disposed below the polishing pad; and a sensor-head cleaning nozzle configured to emit a cleaning liquid to the optical sensor head, the sensor-head cleaning nozzle being disposed in the polishing table and pointing at the optical sensor head.

In an embodiment, the sensor-head cleaning nozzle is disposed at a position higher than the optical sensor head.

In an embodiment, the sensor-head cleaning nozzle is inclined downward with respect to a horizontal direction.

In an embodiment, the sensor-head cleaning nozzle is disposed at the same height as the optical sensor head.

In an embodiment, the sensor-head cleaning nozzle points in a horizontal direction.

In an embodiment, the polishing apparatus further comprises a transparent-liquid inlet passage configured to supply a transparent liquid to the through-hole, wherein the optical sensor head is disposed in the transparent-liquid inlet passage, and the sensor-head cleaning nozzle communicates with the transparent-liquid inlet passage.

In an embodiment, the sensor-head cleaning nozzle comprises a fan-shaped nozzle configured to form a fan-shaped jet of the cleaning liquid.

In an embodiment, the sensor-head cleaning nozzle comprises a multi-nozzle having a plurality of cleaning-liquid outlets arranged around the optical sensor head.

In an embodiment, the sensor-head cleaning nozzle is coupled to a cleaning-liquid supply source which is a pure-water supply source or a chemical-liquid supply source.

In an embodiment, the polishing apparatus further comprises an ultrasonic transducer configured to apply ultrasonic waves to the cleaning liquid supplied to the sensor-head cleaning nozzle.

In an embodiment, the polishing apparatus further comprises: a flow-rate regulation valve coupled to the sensor-head cleaning nozzle; and an operation controller configured to control operation of the flow-rate regulation valve, the operation controller being configured to: instruct the flow-rate regulation valve to cause the sensor-head cleaning nozzle to emit the cleaning liquid at a first flow rate when the workpiece is located over the optical sensor head during polishing of the workpiece; and instruct the flow-rate regulation valve to cause the sensor-head cleaning nozzle to emit the cleaning liquid at a second flow rate higher than the first flow rate when the workpiece is not located over the optical sensor head during polishing of the workpiece.

The flow of the cleaning liquid emitted from the sensor-head cleaning nozzle to the optical sensor head can prevent abrasive grains of the polishing liquid and polishing debris of the workpiece from adhering to the optical sensor head. Therefore, the optical film-thickness measuring system can accurately measure the film thickness of the workpiece based on the intensity of the reflected light from the workpiece.

### BRIEF DESCRIPTION OF THE DRAWINGS

FIG. 1 is a schematic diagram showing an embodiment of a polishing apparatus;

FIG. 2 is a cross-sectional view showing a detailed configuration of an optical film-thickness measuring system;

FIG. 3 is an enlarged cross-sectional view showing an embodiment of an optical sensor head, a transparent-liquid inlet passage, a transparent-liquid outlet passage, and a sensor-head cleaning nozzle;

FIG. 4 is an enlarged cross-sectional view showing another embodiment of the polishing apparatus;

FIG. 5 is a top view of the sensor-head cleaning nozzle and the optical sensor head of the embodiment shown in FIG. 3 or FIG. 4;

FIG. 6 is a top view showing another embodiment of the sensor-head cleaning nozzle;

FIG. 7 is a top view showing another embodiment of the sensor-head cleaning nozzle; and

FIG. 8 is an enlarged cross-sectional view showing still another embodiment of the polishing apparatus.

### DESCRIPTION OF EMBODIMENTS

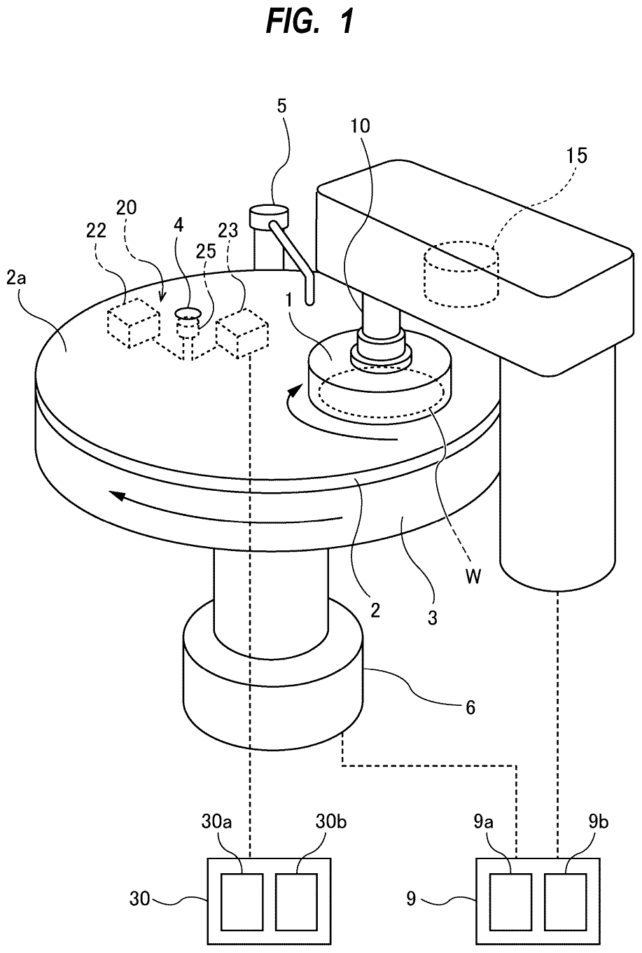

Embodiments will now be described with reference to the drawings. FIG. 1 is a schematic diagram showing an embodiment of a polishing apparatus. As shown in FIG. 1, the polishing apparatus includes a polishing pad 2 having a through-hole 4 formed therein, a polishing table 3 configured to support the polishing pad 2, a polishing head 1 configured to press a workpiece W against the polishing pad 2, a table motor 6 configured to rotate the polishing table 3, a polishing-liquid supply nozzle 5 configured to supply a polishing liquid, such as slurry, onto the polishing pad 2, and an operation controller 9 configured to control operations of the polishing apparatus.

The polishing pad 2 has an upper surface constituting a polishing surface 2a for polishing the workpiece W. The through-hole 4 extends through the polishing pad 2. The workpiece W has a film that constitutes its surface. Examples of the workpiece W to be polished include a wafer, an interconnect substrate, and a quadrangular substrate used in manufacturing of semiconductor devices.

The polishing head 1 is coupled to a head shaft 10, and the head shaft 10 is coupled to a polishing-head rotating device 15. The polishing-head rotating device 15 is configured to rotate the polishing head 1 together with the head shaft 10 in a direction indicated by an arrow. The configuration of the polishing-head rotating device 15 is not particularly limited. In an example, the polishing-head rotating device 15 includes an electric motor, a belt, and pulleys. The polishing table 3 is coupled to the table motor 6, and the table motor 6 is configured to rotate the polishing table 3 and the polishing pad 2 in a direction indicated by an arrow. The polishing head 1, the polishing-head rotating device 15, and the table motor 6 are electrically coupled to the operation controller 9.

Polishing of the workpiece W is performed as follows. The polishing liquid is supplied from the polishing-liquid supply nozzle 5 onto the polishing surface 2a of the polishing pad 2 on the polishing table 3, while the table motor 6 and the polishing-head rotating device 15 rotate the polishing table 3 and the polishing head 1 in the directions indicated by the arrows in FIG. 1. The workpiece W is pressed against the polishing surface 2a of the polishing pad 2 by the polishing head 1 in the presence of the polishing liquid on the polishing pad 2, while the workpiece W is being rotated by the polishing head 1. The surface of the workpiece W is polished by a chemical action of the polishing liquid and mechanical action(s) of abrasive grains contained in the polishing liquid and/or the polishing pad 2.

The operation controller 9 includes a memory 9a storing programs therein, and an arithmetic device 9b configured to perform arithmetic operations according to instructions contained in the programs. The operation controller 9 is composed of at least one computer. The memory 9a includes a main memory, such as a random-access memory (RAM), and an auxiliary memory, such as a hard disk drive (HDD) or a solid state drive (SSD). Examples of the arithmetic device 9b include a CPU (central processing unit) and a GPU (graphic processing unit). However, the specific configuration of the operation controller 9 is not limited to these examples.

The polishing apparatus includes an optical film-thickness measuring system 20 for measuring a film thickness of the workpiece W. The optical film-thickness measuring system 20 includes a light source 22 configured to emit light, an optical sensor head 25 configured to irradiate the workpiece W with the light from the light source 22 and receive reflected light from the workpiece W, a spectrometer 23 coupled to the optical sensor head 25, and a spectrum processor 30 configured to determine a film thickness of the workpiece W based on a spectrum of the reflected light from the workpiece W. The optical sensor head 25 is disposed within the polishing table 3 and rotates together with the polishing table 3.

The spectrum processor 30 includes a memory 30a storing programs therein, and an arithmetic device 30b configured to perform arithmetic operations according to instructions contained in the programs. The spectrum processor 30 is composed of at least one computer. The memory 30a includes a main memory, such as a random-access memory (RAM), and an auxiliary memory, such as a hard disk drive (HDD) or a solid state drive (SSD). Examples of the arithmetic device 30b include a CPU (central processing unit) and a GPU (graphic processing unit). However, the specific configuration of the spectrum processor 30 is not limited to these examples.

Each of the operation controller 9 and the spectrum processor 30 may be composed of a plurality of computers. For example, each of the operation controller 9 and the spectrum processor 30 may be configured of a combination of an edge server and a cloud server. In one embodiment, the operation controller 9 and the spectrum processor 30 may be comprised of one computer.

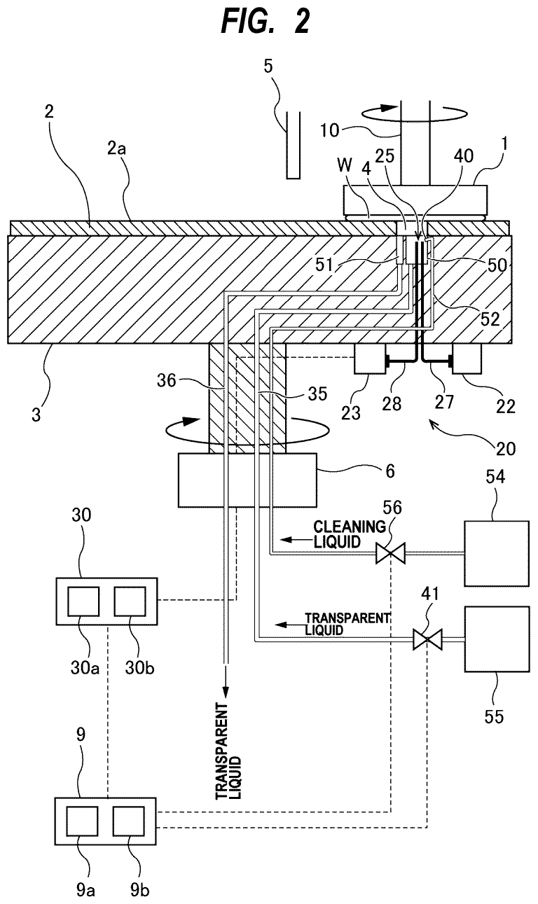

FIG. 2 is a cross-sectional view showing a detailed configuration of the optical film-thickness measuring system 20. The optical sensor head 25 is disposed in the polishing table 3, and the light source 22 and the spectrometer 23 are attached to the polishing table 3. The optical sensor head 25, the light source 22, and the spectrometer 23 rotate together with the polishing table 3 and the polishing pad 2. A position of the optical sensor head 25 is such that the optical sensor head 25 moves across the surface of the workpiece W on the polishing pad 2 each time the polishing table 3 and the polishing pad 2 make one rotation. The optical sensor head 25 is coupled to the light source 22 and the spectrometer 23, and the spectrometer 23 is coupled to the spectrum processor 30.

The optical film-thickness measuring system 20 includes a light-emitting optical fiber cable 27 configured to direct the light, emitted from the light source 22, onto the surface of the workpiece W, and a light-receiving optical fiber cable 28 configured to receive the reflected light from the workpiece W and transmit the reflected light to the spectrometer 23. A distal end of the light-emitting optical fiber cable 27 and a distal end of the light-receiving optical fiber cable 28 constitute the optical sensor head 25 that directs the light to the surface of the workpiece W and receives the reflected light from the workpiece W. Other end of the light-emitting optical fiber cable 27 is coupled to the light source 22, and other end of the light-receiving optical fiber cable 28 is coupled to the spectrometer 23. The spectrometer 23 is configured to resolve the reflected light from the workpiece W according to wavelength of the reflected light and measure intensities of the reflected light over a predetermined wavelength range.

The optical sensor head 25 that is constituted by the distal end of the light-emitting optical fiber cable 27 and the distal end of the light-receiving optical fiber cable 28 is located below the through-hole 4 of the polishing pad 2. The light emitted by the light source 22 travels through the light-emitting optical fiber cable 27, and is emitted from the optical sensor head 25 through the through-hole 4 to the workpiece W. The reflected light from the workpiece W passes through the through-hole 4 and is received by the optical sensor head 25. The reflected light is transmitted to the spectrometer 23 through the light-receiving optical fiber cable 28. The spectrometer 23 resolves the reflected light according to its wavelengths and generates intensity measurement data of the reflected light by measuring the intensity of the reflected light at each of the wavelengths. The intensity measurement data of the reflected light is transmitted from the spectrometer 23 to the spectrum processor 30.

The spectrum processor 30 is configured to generate a spectrum of the reflected light from the workpiece W from the intensity measurement data of the reflected light. The spectrum of the reflected light is expressed as a line graph (i.e., a spectral waveform) representing a relationship between wavelength and intensity of the reflected light. The intensity of the reflected light can also be expressed as a relative value, such as reflectance or relative reflectance.

The spectrum processor 30 is configured to determine the film thickness of the workpiece W based on the spectrum of the reflected light. A known method may be used to determine the film thickness of the workpiece W based on the spectrum. For example, the spectrum processor 30 determines a reference spectrum that is closest in shape to the spectrum of the reflected light from a reference spectrum library, and determines a film thickness associated with the determined reference spectrum. In another example, the spectrum processor 30 performs a Fourier transform on the spectrum of the reflected light, and determines a film thickness from a frequency spectrum obtained.

The polishing apparatus includes a sensor-head cleaning nozzle 40 configured to emit a cleaning liquid toward the optical sensor head 25 and clean the optical sensor head 25 with the cleaning liquid. The sensor-head cleaning nozzle 40 is disposed in the polishing table 3 and rotates together with the polishing table 3. The sensor-head cleaning nozzle 40 is coupled to a cleaning-liquid supply line 52 that extends through the polishing table 3, and the cleaning-liquid supply line 52 is coupled to a cleaning-liquid supply source 54. The sensor-head cleaning nozzle 40 is coupled to the cleaning-liquid supply source 54 via the cleaning-liquid supply line 52. In one embodiment, the sensor-head cleaning nozzle 40 and the cleaning-liquid supply line 52 may be integrally configured.

Examples of the cleaning-liquid supply source 54 include a pure-water supply source that supplies pure water as the cleaning liquid, and a chemical-liquid supply source that supplies a chemical liquid as the cleaning liquid. An example of the chemical liquid is a potassium hydroxide (KOH) solution that has an etching effect. In this embodiment, the cleaning-liquid supply source 54 is the pure-water supply source, and pure water is used as the cleaning liquid. However, the type of the cleaning liquid is not particularly limited as long as the cleaning liquid can clean the optical sensor head 25.

The polishing apparatus further includes a flow-rate regulation valve 56 attached to the cleaning-liquid supply line 52. The flow-rate regulation valve 56 is electrically coupled to the operation controller 9, and operation of the flow-rate regulation valve 56 is controlled by the operation controller 9. The flow-rate regulation valve 56 is coupled to the sensor-head cleaning nozzle 40 via the cleaning-liquid supply line 52. The flow-rate regulation valve 56 is configured to regulate a flow rate of the cleaning liquid flowing through the cleaning-liquid supply line 52. Therefore, the flow rate of the cleaning liquid emitted from the sensor-head cleaning nozzle 40 toward the optical sensor head 25 is regulated by the flow-rate regulation valve 56.

The flow-rate regulation valve 56 is an actuator-driven type, such as an electric valve, an electromagnetic valve, or an air-operated valve. The operation controller 9 can instruct the flow-rate regulation valve 56 to regulate the flow rate of the cleaning liquid discharged from the sensor-head cleaning nozzle 40 toward the optical sensor head 25.

The polishing table 3 has a transparent-liquid inlet passage 50 and a transparent-liquid outlet passage 51 which communicate with the through-hole 4. The transparent-liquid inlet passage 50 and the transparent-liquid outlet passage 51 are provided in the polishing table 3 and rotate together with the polishing table 3. The polishing apparatus 1 includes a transparent-liquid supply line 35 coupled to the transparent-liquid inlet passage 50, a transparent-liquid discharge line 36 coupled to the transparent-liquid outlet passage 51, and a flow-rate regulation valve 41 coupled to the transparent-liquid supply line 35. The flow-rate regulation valve 41 is configured to regulate a flow rate of the transparent liquid flowing through the transparent-liquid supply line 35. Therefore, the flow rate of the transparent liquid supplied to the transparent-liquid inlet passage 50 and the through-hole 4 is regulated by the flow-rate regulation valve 41.

One end of the transparent-liquid supply line 35 is coupled to the transparent-liquid inlet passage 50, and other end is coupled to a transparent-liquid supply source 55. The transparent-liquid inlet passage 50 may be configured integrally with the transparent-liquid supply line 35. An example of the transparent-liquid supply source 55 is a pure-water supply source that supplies pure water as the transparent liquid. The transparent liquid (e.g., pure water) is supplied into the through-hole 4 of the polishing pad 2 through the transparent-liquid supply line 35 and the transparent-liquid inlet passage 50. The transparent liquid that has been supplied into the through-hole 4 of the polishing pad 2 is discharged from the through-hole 4 through the transparent-liquid outlet passage 51, and further discharged through the transparent-liquid discharge line 36. The transparent-liquid outlet passage 51 may be configured integrally with the transparent-liquid discharge line 36.

The through-hole 4 of the polishing pad 2 is filled with the transparent liquid during polishing of the workpiece W. The flow of transparent liquid in the through-hole 4 can restrict intrusion of the polishing liquid and polishing debris of the workpiece W into the transparent-liquid inlet passage 50.

The flow-rate regulation valve 41 is an actuator-driven type, such as an electric valve, an electromagnetic valve, or an air-operated valve. The operation controller 9 can instruct the flow-rate regulation valve 41 to regulate the flow rate of the transparent liquid supplied to the transparent-liquid inlet passage 50.

During polishing of the workpiece W, the polishing pad 2 rotates together with the polishing table 3, while the workpiece W held by the polishing head 1 does not rotate together with the polishing table 3. Therefore, there are times when the workpiece W is located over the optical sensor head 25 and times when the workpiece W is not located over the optical sensor head 25.

In one embodiment, when the workpiece W is located over the optical sensor head 25, the operation controller 9 instructs the flow-rate regulation valve 41 to supply the transparent liquid to the transparent-liquid inlet passage 50 at a preset measurement flow rate, and when the workpiece W is not located over the optical sensor head 25, the operation controller 9 instructs the flow-rate regulation valve 41 to supply the transparent liquid to the transparent-liquid inlet passage 50 at a flow rate lower than the measurement flow rate, or stops the supply of the transparent liquid to the transparent-liquid inlet passage 50. Such operations can make it possible to prevent the polishing liquid on the polishing pad 2 from being diluted with the transparent liquid (e.g., pure water) when the workpiece W is not located over the optical sensor head 25.

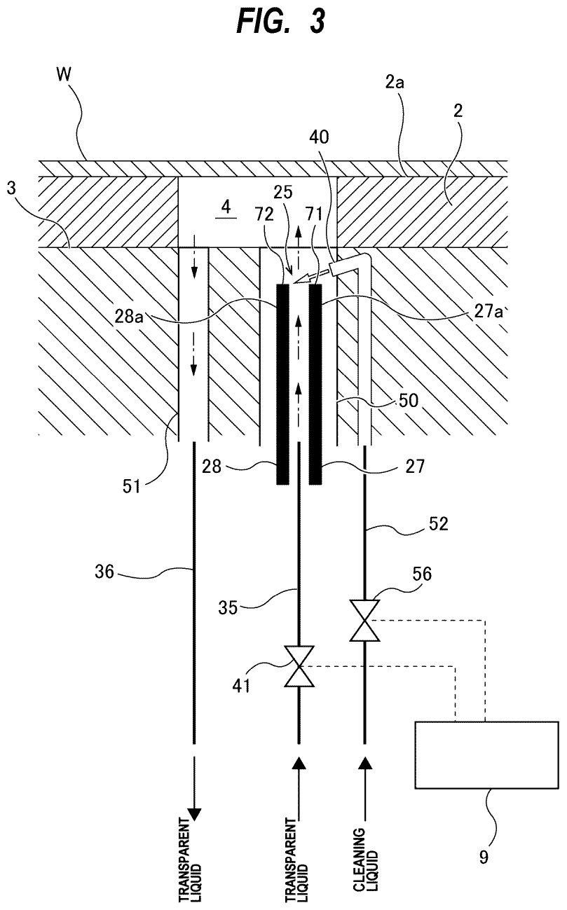

FIG. 3 is an enlarged cross-sectional view showing one embodiment of the optical sensor head 25, the transparent-liquid inlet passage 50, the transparent-liquid outlet passage 51, and the sensor-head cleaning nozzle 40. As shown in FIG. 3, the optical sensor head 25, which is composed of end 27a of the light-emitting optical fiber cable 27 and end 28a of the light-receiving optical fiber cable 28, is located below the through-hole 4 of the polishing pad 2. The optical sensor head 25 is oriented toward the through-hole 4.

The optical sensor head 25 has a light-emitting surface 71 configured to emit the light and a light-receiving surface 72 configured to receive the reflected light from the workpiece W. In this embodiment, the light-emitting surface 71 is composed of an end surface of the light-emitting optical fiber cable 27, and the light-receiving surface 72 is composed of an end surface of the light-receiving optical fiber cable 28. In one embodiment, the light-emitting surface 71 and the light-receiving surface 72 may be comprised of optical elements, such as lens or glass attached to the ends 27a, 28a of the light-emitting optical fiber cable 27 and the light-receiving optical fiber cable 28.

The transparent-liquid inlet passage 50 and the transparent-liquid outlet passage 51 have upper ends that open in an upper surface of the polishing table 3 and communicate with the through-hole 4. The transparent-liquid outlet passage 51 is adjacent to the transparent-liquid inlet passage 50. The optical sensor head 25 is disposed in the transparent-liquid inlet passage 50. The light-emitting surface 71 of the optical sensor head 25 emits the light toward the surface of the workpiece W and directs the light to the surface of the workpiece W. The reflected light from the workpiece W travels toward the light-receiving surface 72 of the optical sensor head 25 and is incident on the light-receiving surface 72.

During polishing of the workpiece W, the through-hole 4 is filled with the transparent liquid (e.g., pure water). The light emitted from the optical sensor head 25, which is composed of the end 27a of the light-emitting optical fiber cable 27 and the end 28a of the light-receiving optical fiber cable 28, passes through the pure water filling the through-hole 4 and irradiates the workpiece W on the polishing pad 2. The reflected light from the workpiece W passes through the pure water filling the through-hole 4 and is received by the optical sensor head 25.

The sensor-head cleaning nozzle 40 is disposed in the polishing table 3 and located adjacent to the optical sensor head 25. The sensor-head cleaning nozzle 40 communicates with the transparent-liquid inlet passage 50. As shown in FIG. 3, a distal end of the sensor-head cleaning nozzle 40 may protrude into the transparent-liquid inlet passage 50. Relative position of the sensor-head cleaning nozzle 40 and the optical sensor head 25 is fixed. The sensor-head cleaning nozzle 40 and the optical sensor head 25 rotate together with the polishing table 3 and the polishing pad 2.

The sensor-head cleaning nozzle 40 points at the optical sensor head 25 and is configured to emit the cleaning liquid to the optical sensor head 25. More specifically, the sensor-head cleaning nozzle 40 points at the light-emitting surface 71 and the light-receiving surface 72 of the optical sensor head 25 and cleans the light-emitting surface 71 and the light-receiving surface 72 of the optical sensor head 25 with the cleaning liquid. In this embodiment, the sensor-head cleaning nozzle 40 is disposed at a position higher than the light-emitting surface 71 and the light-receiving surface 72 of the optical sensor head 25. The sensor-head cleaning nozzle 40 is inclined downward with respect to a horizontal direction. Therefore, the sensor-head cleaning nozzle 40 emits the cleaning liquid obliquely downward toward the light-emitting surface 71 and the light-receiving surface 72 of the optical sensor head 25.

The flow of the cleaning liquid discharged from the sensor-head cleaning nozzle 40 comes into contact with the light-emitting surface 71 and the light-receiving surface 72 of the optical sensor head 25, and can prevent the abrasive grains contained in the polishing liquid and the polishing debris of the workpiece W from adhering to the light-emitting surface 71 and the light-receiving surface 72. Therefore, the light-emitting surface 71 and the light-receiving surface 72 of the optical sensor head 25 can be kept clean.

The light-receiving surface 72 of the optical sensor head 25 receives the reflected light from the workpiece W. The optical film-thickness measuring system 20 can accurately measure the film thickness of the workpiece W based on the intensity of the reflected light from the workpiece W.

During polishing of the workpiece W, the flow-rate regulation valve 56 is opened, so that the cleaning liquid is supplied to the sensor-head cleaning nozzle 40 through the cleaning-liquid supply line 52.

The flow-rate regulation valve 56 is coupled to the sensor-head cleaning nozzle 40 through the cleaning-liquid supply line 52. This flow-rate regulation valve 56 can regulate the flow rate of the cleaning liquid emitted from the sensor-head cleaning nozzle 40 toward the optical sensor head 25. The operation of the flow-rate regulation valve 56 is controlled by the operation controller 9. In one embodiment, the flow rate of the cleaning liquid emitted from the sensor-head cleaning nozzle 40 is maintained constant by the flow-rate regulation valve 56 during polishing of the workpiece W.

In one embodiment, when the workpiece W is located over the optical sensor head 25 during polishing of the workpiece W, the operation controller 9 instructs the flow-rate regulation valve 41 to supply the transparent liquid to the transparent-liquid inlet passage 50 at a preset measurement flow rate, while instructing the flow-rate regulation valve 56 to cause the sensor-head cleaning nozzle 40 to emit the cleaning liquid at a first flow rate. When the workpiece W is not located over the optical sensor head 25 during polishing of the workpiece W, the operation controller 9 instructs the flow-rate regulation valve 41 to supply the transparent liquid to the transparent-liquid inlet passage 50 at a flow rate lower than the measurement flow rate, while instructing the flow-rate regulation valve 56 to cause the sensor-head cleaning nozzle 40 to emit the cleaning liquid at a second flow rate higher than the first flow rate. According to such operations, when the workpiece W is not located over the optical sensor head 25, a strong flow of the cleaning liquid is formed in the transparent-liquid inlet passage 50, so that the cleaning liquid can reach the optical sensor head 25 without being hindered by the flow of the transparent liquid. Therefore, the cleaning effect of the cleaning liquid on the optical sensor head 25 can be improved.

In one embodiment, the transparent-liquid supply line 35 and the transparent-liquid supply source 55 may be omitted if the flow rate of the cleaning liquid is high enough to prevent the polishing liquid and polishing debris of the workpiece W from entering the transparent-liquid inlet passage 50.

In one embodiment, cleaning of the optical sensor head 25 with the cleaning liquid may be performed before or after polishing of the workpiece W. In this case, the supply of the transparent liquid to the transparent-liquid inlet passage 50 and the through-hole 4 is stopped during cleaning of the optical sensor head 25. When the chemical-liquid supply source is used as the cleaning-liquid supply source 54 (see FIG. 2), i.e., when a chemical liquid is used as the cleaning liquid, cleaning of the optical sensor head 25 may be performed during polishing of the workpiece W under conditions that the chemical liquid is allowed to flow onto the polishing pad 2. Under conditions that it is undesirable for the chemical liquid to flow onto the polishing pad 2, cleaning of the optical sensor head 25 with the chemical liquid may be performed before or after polishing of the workpiece W.

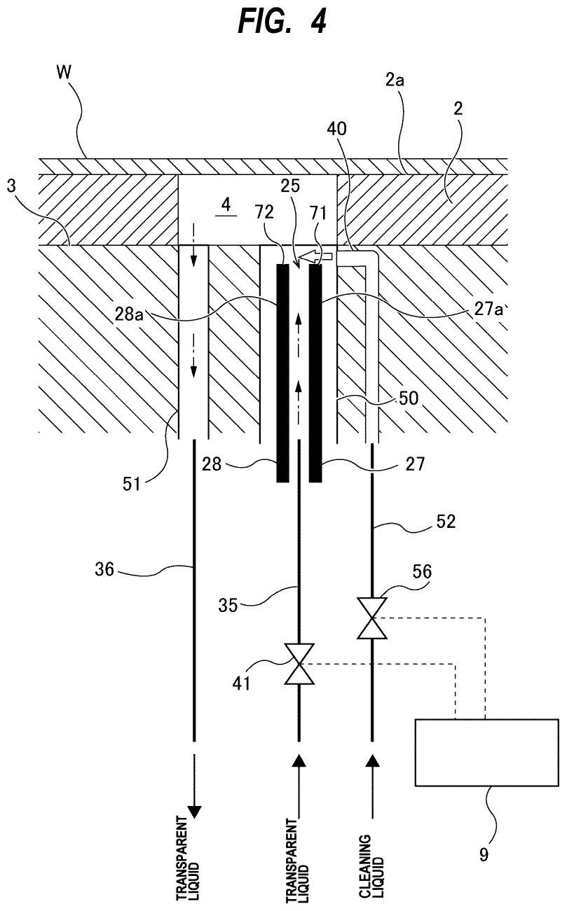

FIG. 4 is an enlarged cross-sectional view showing another embodiment of the polishing apparatus. Configurations and operations of this embodiment, which are not specifically described, are the same as those of the embodiment described with reference to FIGS. 1 to 3, and therefore duplicated descriptions will be omitted.

The embodiment shown in FIG. 4 is the same as the embodiments described with reference to FIGS. 1 to 3 in that the sensor-head cleaning nozzle 40 points at the light-emitting surface 71 and the light-receiving surface 72 of the optical sensor head 25, but differs in that the sensor-head cleaning nozzle 40 is located at the same height as the light-emitting surface 71 and the light-receiving surface 72 of the optical sensor head 25, and the sensor-head cleaning nozzle 40 points in the horizontal direction.

The flow of the cleaning liquid emitted from the sensor-head cleaning nozzle 40 comes into contact with the light-emitting surface 71 and the light-receiving surface 72 of the optical sensor head 25, and can prevent the abrasive grains contained in the polishing liquid and the polishing debris of the workpiece W from adhering to the light-emitting surface 71 and the light-receiving surface 72. Therefore, the light-emitting surface 71 and the light-receiving surface 72 of the optical sensor head 25 can be kept clean.

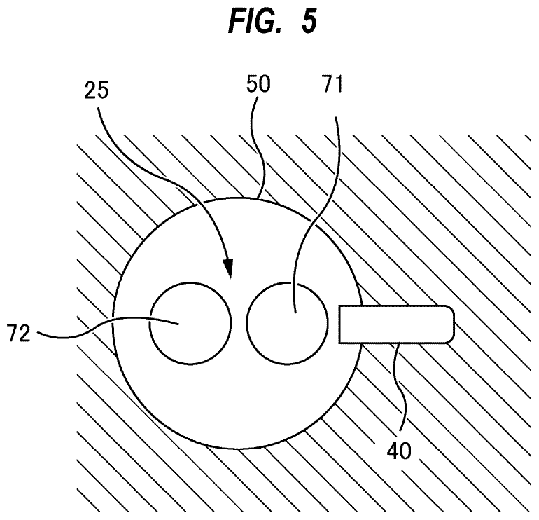

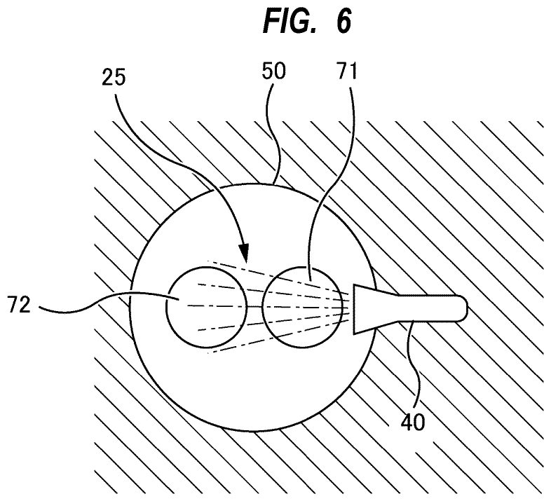

FIG. 5 is a top view of the sensor-head cleaning nozzle 40 and the optical sensor head 25 of the embodiment shown in FIG. 3 or FIG. 4. As shown in FIG. 5, the sensor-head cleaning nozzle 40 faces the light-emitting surface 71 and the light-receiving surface 72 of the optical sensor head 25. In one embodiment, as shown in FIG. 6, the sensor-head cleaning nozzle 40 may be a fan-shaped nozzle configured to form a fan-shaped jet of the cleaning liquid. The fan-shaped nozzle can direct the cleaning liquid over a wide area.

In the embodiments shown in FIGS. 5 and 6, the sensor-head cleaning nozzle 40 is located closer to the light-emitting surface 71 than to the light-receiving surface 72 of the optical sensor head 25, while the relative position of the sensor-head cleaning nozzle 40 with respect to the optical sensor head 25 is not particularly limited, as long as the cleaning liquid released from the sensor-head cleaning nozzle 40 can contact both the light-emitting surface 71 and the light-receiving surface 72.

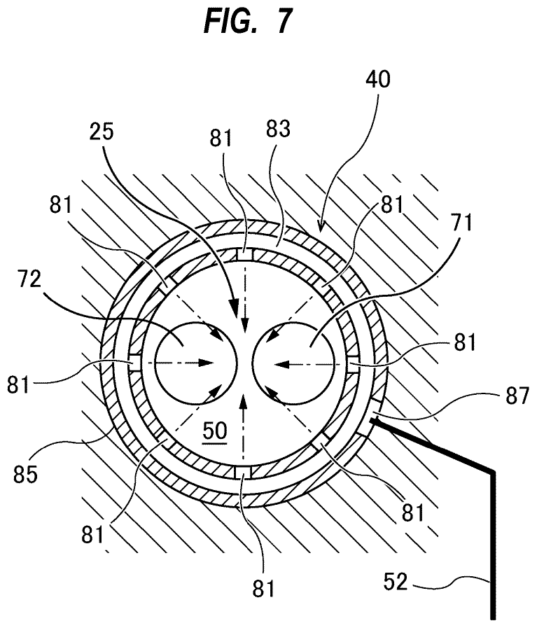

In one embodiment, as shown in FIG. 7, the sensor-head cleaning nozzle 40 may be a multi-nozzle having a plurality of cleaning-liquid outlets 81 arranged around the optical sensor head 25. The sensor-head cleaning nozzle 40 of the embodiment shown in FIG. 7 includes a flow-path structure 85 having the plurality of cleaning-liquid outlets 81 and a cleaning-liquid flow path 83. The flow-path structure 85 extends around the optical sensor head 25. The cleaning-liquid flow path 83 extends around the optical sensor head 25 and communicates with the plurality of cleaning-liquid outlets 81.

The flow-path structure 85 has a cleaning-liquid inlet 87 communicating with the cleaning-liquid flow path 83. This cleaning-liquid inlet 87 is coupled to the cleaning-liquid supply line 52. The cleaning liquid is supplied from the cleaning-liquid supply line 52 through the cleaning-liquid inlet 87 into the cleaning-liquid flow path 83, and is emitted from the plurality of cleaning-liquid outlets 81 to the optical sensor head 25. The plurality of cleaning-liquid outlets 81 face inward in the radial direction of the transparent-liquid inlet passage 50 when viewed from above.

The flows of the cleaning liquid discharged from the plurality of cleaning-liquid outlets 81 contact the light-emitting surface 71 and the light-receiving surface 72 of the optical sensor head 25, and can prevent abrasive grains contained in the polishing liquid and polishing debris of the workpiece W from adhering to the light-emitting surface 71 and the light-receiving surface 72. Therefore, the light-emitting surface 71 and the light-receiving surface 72 of the optical sensor head 25 can be kept clean.

Although not shown, another embodiment of the multi-nozzle having the plurality of cleaning-liquid outlets 81 may be multiple nozzles having a plurality of cleaning-liquid outlets 81 arranged around the optical sensor head 25.

The embodiments described with reference to FIGS. 6 and 7 are applicable to the embodiments described below.

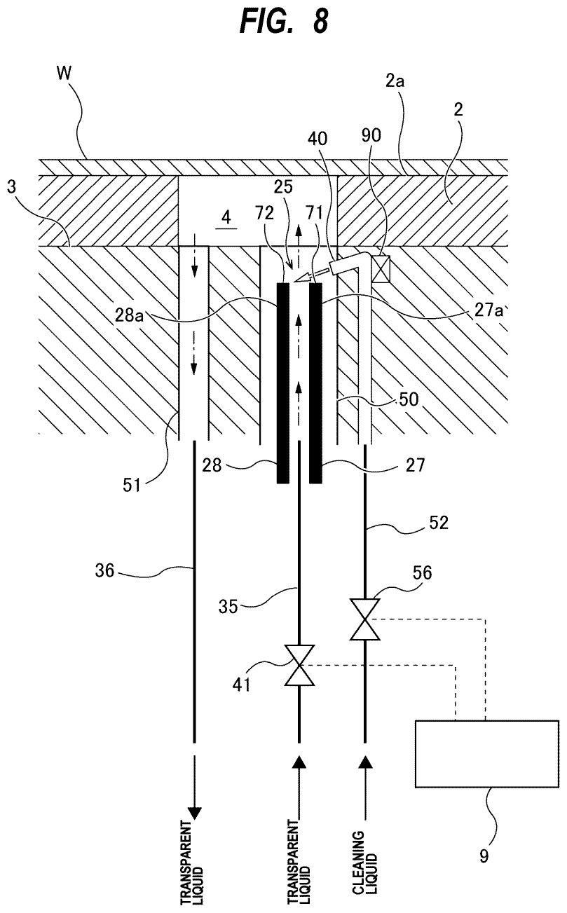

FIG. 8 is an enlarged cross-sectional view showing another embodiment of the polishing apparatus. Configurations and operations of this embodiment, which will not be specifically described, are the same as those of the embodiment described with reference to FIGS. 1 to 3, and therefore repetitive descriptions will be omitted. In this embodiment, the polishing apparatus includes an ultrasonic transducer 90 configured to apply ultrasonic waves to the cleaning liquid supplied to the sensor-head cleaning nozzle 40. The ultrasonic transducer 90 is installed in the polishing table 3 and is adjacent to the sensor-head cleaning nozzle 40. The ultrasonic transducer 90 may be attached to the sensor-head cleaning nozzle 40. In one embodiment, the ultrasonic transducer 90 may be attached to the cleaning-liquid supply line 52 coupled to the sensor-head cleaning nozzle 40.

According to this embodiment, the cleaning liquid to which ultrasonic waves have been applied by the ultrasonic vibrator 90 is emitted from the sensor-head cleaning nozzle 40, and can effectively clean the light-emitting surface 71 and the light-receiving surface 72 of the optical sensor head 25.

The embodiment described with reference to FIG. 8 is applicable to the embodiments described with reference to FIGS. 4 to 7.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A polishing apparatus comprising:
a polishing table configured to support a polishing pad having a through-hole;
a polishing head configured to press a workpiece against the polishing pad;
an optical film-thickness measuring system having an optical sensor head disposed below the polishing pad; and
a sensor-head cleaning nozzle configured to emit a cleaning liquid to the optical sensor head, the sensor-head cleaning nozzle being disposed in the polishing table and pointing at the optical sensor head.

2. The polishing apparatus according to claim 1, wherein the sensor-head cleaning nozzle is disposed at a position higher than the optical sensor head.

3. The polishing apparatus according to claim 2, wherein the sensor-head cleaning nozzle is inclined downward with respect to a horizontal direction.

4. The polishing apparatus according to claim 1, wherein the sensor-head cleaning nozzle is disposed at the same height as the optical sensor head.

5. The polishing apparatus according to claim 4, wherein the sensor-head cleaning nozzle points in a horizontal direction.

6. The polishing apparatus according to claim 1, further comprising a transparent-liquid inlet passage configured to supply a transparent liquid to the through-hole,
wherein the optical sensor head is disposed in the transparent-liquid inlet passage, and
the sensor-head cleaning nozzle communicates with the transparent-liquid inlet passage.

7. The polishing apparatus according to claim 1, wherein the sensor-head cleaning nozzle comprises a fan-shaped nozzle configured to form a fan-shaped jet of the cleaning liquid.

8. The polishing apparatus according to claim 1, wherein the sensor-head cleaning nozzle comprises a multi-nozzle having a plurality of cleaning-liquid outlets arranged around the optical sensor head.

9. The polishing apparatus according to claim 1, wherein the sensor-head cleaning nozzle is coupled to a cleaning-liquid supply source which is a pure-water supply source or a chemical-liquid supply source.

10. The polishing apparatus according to claim 1, further comprising an ultrasonic transducer configured to apply ultrasonic waves to the cleaning liquid supplied to the sensor-head cleaning nozzle.

11. The polishing apparatus according to claim 1, further comprising:
a flow-rate regulation valve coupled to the sensor-head cleaning nozzle; and
an operation controller configured to control operation of the flow-rate regulation valve, the operation controller being configured to:
instruct the flow-rate regulation valve to cause the sensor-head cleaning nozzle to emit the cleaning liquid at a first flow rate when the workpiece is located over the optical sensor head during polishing of the workpiece; and
instruct the flow-rate regulation valve to cause the sensor-head cleaning nozzle to emit the cleaning liquid at a second flow rate higher than the first flow rate when the workpiece is not located over the optical sensor head during polishing of the workpiece.
